(19) United States
(12) Patent Application Publication
(10) Pub. No.: US 2026/0068509 A1
(43) Pub. Date: Mar. 5, 2026

(54) DISPLAY DEVICE, ELECTRONIC DEVICE INCLUDING THE SAME, AND METHOD OF MANUFACTURING THE SAME

(71) Applicant: Samsung Display Co., LTD., Yongin-si (KR)

(72) Inventor: JAEWOO JEONG, Yongin-si (KR)

(21) Appl. No.: 19/077,634

(22) Filed: Mar. 12, 2025

(30) Foreign Application Priority Data
Sep. 4, 2024 (KR) 10-2024-0119817

(51) Int. Cl. H10K 59/80; H10K 59/12

(52) U.S. Cl. CPC H10K 59/8792; H10K 59/1201

(57) ABSTRACT

A display device and a method of manufacturing a display device are disclosed. The display device may include a substrate, a circuit layer on the substrate, a display layer provided on the circuit layer and including a plurality of light-emitting layers, an inorganic insulating (e.g., electrically insulating) player on the display player, and a light control layer including a plurality of light-shielding patterns on the inorganic insulating layer and organic light-transmitting patterns between the plurality of light-shielding patterns. The organic light-transmitting patterns may contact the inorganic insulating layer, and the upper portion of the inorganic insulating layer may be doped with ions. The plurality of light-shielding patterns and the organic light-transmitting patterns may extend in the first direction and may be alternately arranged or provided in the second direction that crosses (e.g., intersects) the first direction.

### CROSS-REFERENCE TO RELATED APPLICATION

The present application claims priority to and the benefit of Korean Patent Application No. 10-2024-0119817, filed on Sep. 4, 2024, in the Korean Intellectual Property Office, the entire disclosure of which is incorporated herein by reference.

### BACKGROUND

### 1. Field

One or more embodiments of the present disclosure relate to a display device, an electronic device including the display device, and a method of manufacturing the display device, and, for example, to a display device having improved or enhanced reliability (e.g., structural reliability), an electronic device including the display device, and a method of manufacturing the display device.

### 2. Description of the Related Art

A display device may include a flat panel display, such as a liquid crystal display, a field emission display, and/or a light emitting display. The light emitting display devices may include an organic light emitting display device that includes an organic light emitting diode as a light-emitting element and/or a light emitting diode display device that includes an inorganic light emitting diode element, such as a light emitting diode (LED) as a light-emitting element.

As the applications of display devices have become more diversified in recent times, the desired or required features of display devices also vary depending on the specific fields of application. For example, in the case of a display device used in head-up displays for vehicles, it is desirable to have a feature that ensures or provides clear visibility without obstructing the driver's view while displaying images.

### SUMMARY

One or more aspects of embodiments of the present disclosure are directed toward a display device having improved or enhanced reliability (e.g., structural reliability) by increasing or enhancing the adhesion of the organic light-transmitting patterns.

One or more aspects of embodiments of the present disclosure are directed toward a manufacturing method for a display device (or a method of manufacturing a display device) having improved or enhanced reliability (e.g., structural reliability) by increasing or enhancing the adhesion of the organic light-transmitting patterns.

Additional aspects of embodiments will be set forth in part in the description which follows and, in part, will be apparent from the description or may be learned by practice of the presented embodiments of the disclosure.

A display device according to one or more embodiments of the present disclosure may include a substrate; a circuit layer on the substrate; a display layer provided on the circuit layer and including a plurality of light-emitting layers; an inorganic insulating (e.g., electrically insulating) layer on the display layer; and a light control layer including a plurality of light-shielding patterns on the inorganic insulating layer, and a plurality of organic light-transmitting patterns therebetween.

In one or more embodiments, the organic light-transmitting patterns may contact the inorganic insulating layer, and the upper portion of the inorganic insulating layer may be doped with ions.

In one or more embodiments, the plurality of light-shielding patterns and the organic light-transmitting patterns may be extended in a first direction, and the light-shielding patterns and the organic light-transmitting patterns may be alternately arranged or provided in a second direction that crosses (e.g., intersects) the first direction.

In one or more embodiments, the organic light-transmitting patterns may have a greater height in a third direction, which crosses (e.g., intersects) the second direction, than a width in the second direction.

In one or more embodiments, a first area that is relatively proximal to the light control layer and a second area that is relatively distal from the light control layer may be defined in the inorganic insulating layer, and the ions may have a greater concentration in the first area than in the second area.

In one or more embodiments, the ions may include boron ions.

In one or more embodiments, a concentration peak of the ions may be at a depth equal to or less than about 700 Å from an upper surface of the inorganic insulating layer.

In one or more embodiments, the ions may include fluoride ions.

In one or more embodiments, a concentration peak of the ions may be at a depth equal to or less than about 500 Å from an upper surface of the inorganic insulating layer.

In one or more embodiments, the ions may include at least one selected from phosphorus ions and arsenic ions.

A display device according to one or more embodiments of the present disclosure may further include a touch sensing layer that is between the display layer and the inorganic insulating layer.

In one or more embodiments, a vertical control area and a horizontal control area that is spaced and/or apart (e.g., spaced apart or separated) from the vertical control area may be defined in the substrate, and the light control layer may include a first light control layer that is in the vertical control area and a second light control layer that is in the horizontal control area.

In one or more embodiments, the first light control layer may include first light-shielding patterns that extend in the first direction, and the second light control layer may include second light-shielding patterns that extend in a second direction that crosses (e.g., intersects) the first direction.

A manufacturing method of a display device (or a method of manufacturing a display device) according to one or more embodiments of the present disclosure may include: forming or providing a circuit layer on a substrate; forming or providing a display layer including a plurality of light-emitting layers on the circuit layer; forming or providing an inorganic insulating (e.g., electrically insulating) layer on the display layer; doping the inorganic insulating layer with ions downwardly from an upper portion of the inorganic insulating layer; forming or providing an organic light-transmitting film on the ion-doped inorganic insulating layer; forming or providing organic light-transmitting patterns by patterning the organic light-transmitting film; and forming or providing light-shielding patterns between the organic light-transmitting patterns.

In one or more embodiments, the doping of the inorganic insulating layer with ions may include doping the inorganic insulating layer with boron ions.

In one or more embodiments, the doping of the inorganic insulating layer with ions may include doping the inorganic insulating layer with fluoride ions.

In one or more embodiments, the doping of the inorganic insulating layer with ions may include doping the inorganic insulating layer with boron ions and/or fluoride ions.

A manufacturing method of a display device (or a method of manufacturing a display device) according to one or more embodiments of the present disclosure may further include forming or providing a touch sensing layer between the display layer and the inorganic insulating layer.

In one or more embodiments, the forming or providing of the organic light-transmitting patterns may be forming or providing organic light-transmitting patterns that extend in a first direction on the vertical control area defined on the substrate and forming or providing organic light-transmitting patterns that extend in a second direction, that crosses (e.g., intersects) the first direction, on a horizontal control area, that is spaced and/or apart (e.g., spaced apart or separated) from the vertical control area, defined on the substrate.

In one or more embodiments, the doping of the inorganic insulating layer with ions may include injecting ions at an acceleration voltage greater than or equal to about 5 keV and smaller than or equal to about 10 keV.

A display device according to one or more embodiments of the present disclosure may include a substrate; a circuit layer on the substrate; a display layer provided on the circuit layer and having a plurality of light-emitting layers; an inorganic insulating (e.g., electrically insulating) layer on the display layer; and a plurality of organic light-transmitting patterns that extend in a first direction on the inorganic insulating layer.

In one or more embodiments, the organic light-transmitting patterns may be spaced and/or apart (e.g., spaced apart or separated) from each other in a second direction that crosses (e.g., intersects) the first direction, the organic light-transmitting patterns may contact the inorganic insulating layer, and the upper portion of the inorganic insulating layer may be doped with ions.

A display device according to one or more embodiments of the present disclosure may further include light-shielding patterns between the organic light-transmitting patterns.

In one or more embodiments, the ions may include at least one selected from boron ions and fluoride ions.

A display device according to one or more embodiments may further include a touch sensing layer between the display layer and the inorganic insulating layer.

A display device according to one or more embodiments of the present disclosure may provide increased or enhanced adhesion of the organic light-transmitting patterns by doping the upper portion of the inorganic insulating layer with ions.

A display device according to one or more embodiments of the present disclosure may have improved or enhanced reliability (e.g., structural reliability) by directly placing or providing the organic light-emitting patterns on the inorganic insulating layer.

According to one or more embodiments, an electronic device includes the display device as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

The above and/or other aspects and features of certain embodiments of the present disclosure will become more apparent and more readily appreciated from the following description of one or more embodiments, taken in conjunction with the accompanying drawings in which:

FIG. 1 is a plan view illustrating a display device according to one or more embodiments of the present disclosure;

FIG. 2 is a cross-sectional view taken along the line I-I′ of FIG. 1;

FIG. 3 is a perspective view illustrating a portion of a display device according to one or more embodiments of the present disclosure;

FIG. 4 is an enlarged view of an area demarcated with AA in FIG. 1;

FIG. 5 is a cross-sectional view illustrating a portion of a display device according to one or more embodiments;

FIGS. 6 and 7 are graphs illustrating the ion concentration relative to the depth of the inorganic insulating layer;

FIG. 8 is a plan view illustrating a display device according to one or more embodiments;

FIG. 9 is a perspective view illustrating a portion of a display device according to one or more embodiments;

FIG. 10 is a perspective view illustrating a portion of a display device according to one or more embodiments; and FIGS. 11A-11I are diagrams illustrating the methods of manufacturing a display device according to one or more embodiments of the present disclosure.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the accompanying drawings and the written description, and duplicative descriptions thereof may not be provided in the specification.

If (e.g., when) an element is described to be “disposed on,” “provided on,” “placed on,” “arranged on,” “connected to,” or “coupled to” another element, it shall be construed as being disposed on, provided on, placed on, arranged on, connected to, or coupled to the other element directly but also as possibly having another element therebetween. In contrast, if (e.g., when) an element is referred to as being “directly on,” “directly connected to,” or “directly coupled to” another element, there may be no intervening elements present therebetween.

The terms, such as “below,” “lower,” “above,” “upper,” and/or the like, are used herein for ease of description to describe one element's relation to another element(s) as illustrated in the drawings. These terms are relative concepts and are described based on the directions indicated in the drawings.

Like or identical reference numerals refer to like or identical elements. Moreover, in the accompanying drawings, thicknesses, ratios, and dimensions of the elements may not be to exact scale and may have been exaggerated to effectively or suitably illustrate the technical contents of the present disclosure.

The term “and/or” shall include the combination of a plurality of listed items or any of the plurality of listed items.

The terms, such as “first,” “second,” and/or the like, may be used to describe one or more elements, but these elements shall not be restricted to these terms. These terms may be used to distinguish one element from the other. For instance, the first element may be termed the second element, and vice versa, without departing from the spirit and scope of the present disclosure. Unless clearly indicated otherwise, any expressions in a singular form may include a plural form.

For effective description of the technical contents, the sizes of the elements in the drawings may be exaggerated or reduced. For example, the sizes and thicknesses of the elements illustrated in the drawings are represented arbitrarily for ease of illustration, hence embodiments of the present disclosure are not necessarily limited to what is depicted.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms, including technical terms and scientific terms, used herein have substantially the same meaning as how they are generally understood by those of ordinary skill in the art to which the present disclosure pertains. Any term that is defined in a general dictionary shall be construed to have substantially the same meaning in the context of the relevant art and, unless otherwise defined explicitly, shall not be interpreted to have an idealistic or excessively formalistic meaning.

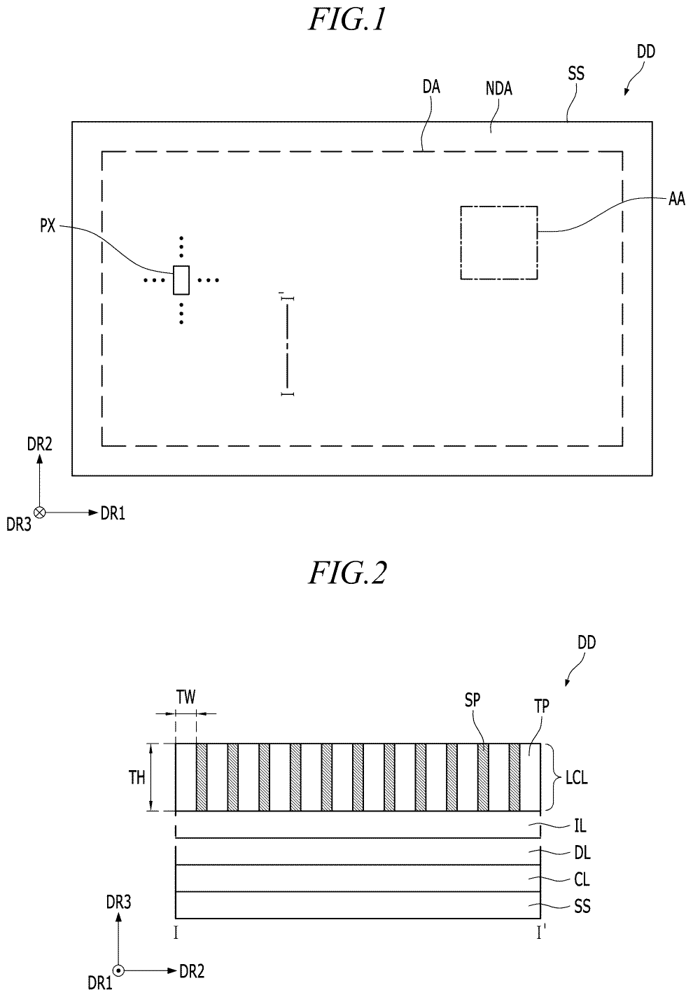

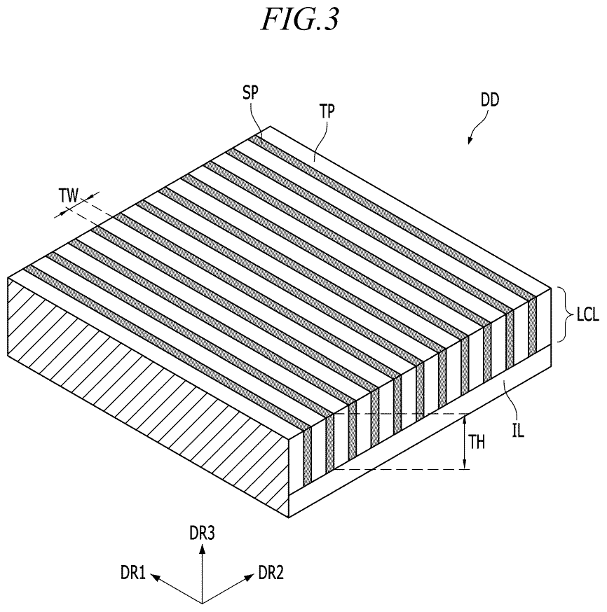

A first direction DR1, a second direction DR2, and a third direction DR3 may be defined as described in one or more embodiments. The first direction DR1 and the second direction DR2 may be directions defined on the plane of the display device DD as illustrated in FIG. 1, that cross (e.g., intersect) each other. The third direction DR3 may be a thickness direction of the display device DD as defined in FIG. 2.

The display device DD as described herein may be a device to display videos (or moving images) and/or still images and may be used as a display screen for one or more suitable products, including not only portable electronic devices, such as mobile phones, smartphones, tablet PCs, smartwatches, watch phones, mobile communication terminals, electronic notebooks, e-books, portable multimedia players(PMPs), navigation systems, and/or ultra-mobile PCs (UMPC), but also televisions, laptops, monitors, billboards, Internet of Things (IOT) devices, and/or automotive head-up displays (HUDs). The display device DD may be one of an organic light-emitting diode display, a liquid crystal display, a plasma display, a field emission display, an electrophoretic display, an electrowetting display, a quantum dot light-emitting display, or a micro-LED display.

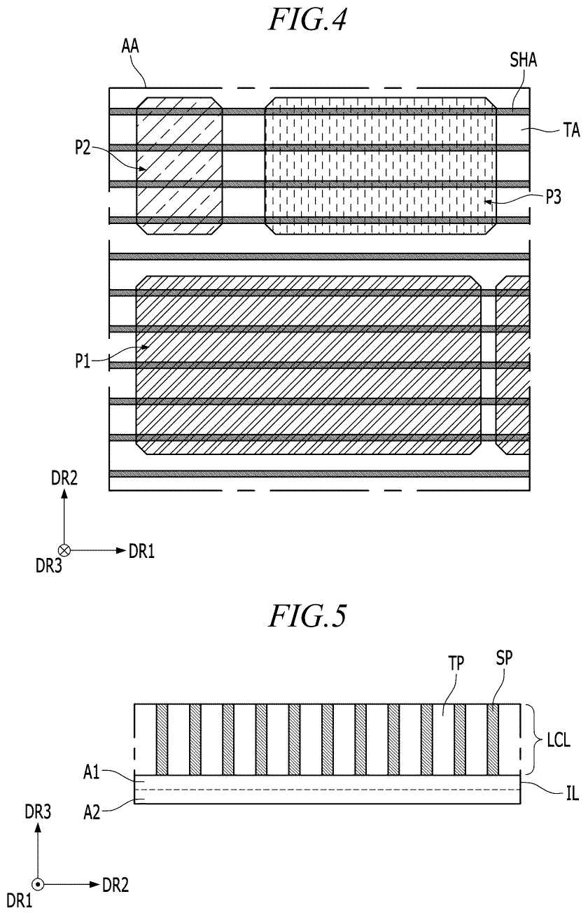

FIG. 1 is a plan view illustrating one or more embodiments of the present disclosure. FIG. 2 is a cross-sectional view taken along the line I-I′ of FIG. 1. FIG. 3 is a perspective view illustrating a portion of the display device according to one or more embodiments of the present disclosure. For ease of explanation, the components other than the inorganic insulating layer IL and the light control layer LCL are not provided in FIG. 3.

Referring to FIG. 1, a display area DA and a non-display area NDA outside the display area DA may be defined on one or more embodiments of a display device DD. The display area DA may be an area defined on a plane and may be substantially identically defined for the substrate SS and its upper components, as described in one or more embodiments. The display area DA is illustrated as having a rectangular shape (e.g., a substantially rectangular shape) in FIG. 1, but embodiments of the present disclosure are not limited thereto. The display area DA may take one or more suitable shapes, such as circular (e.g., substantially circular), elliptical (e.g., substantially elliptical), or polygonal (e.g., substantially polygonal).

The display area DA may be an area where images are displayed. A plurality of pixels PX that render images may be placed or provided in the display area DA. The pixels PX may be in a matrix pattern along the first direction DR1 and the second direction DR2. A display device DD may display one or more images by controlling the pixels PX.

A non-display area NDA may be an area where the pixels PX are not placed or provided and may not display images. The components to actuate the pixels PX, such as a power supply wiring, a printed circuit board having a driving circuit, and a terminal portion where a drive IC is connected, may be placed or provided in the non-display area NDA.

Referring to FIG. 2, the display device DD may include a substrate SS, a circuit layer CL, a display layer DL, an inorganic insulating layer IL, and a light control layer LCL.

The substrate SS may serve as a base surface on which a display layer DL is disposed or provided. The substrate SS may include glass and/or a polymer resin. For example, the polymer resin may include polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate SS including a polymer resin may have flexible, rollable, and/or bendable properties. The substrate SS may also have a multilayer structure including polymer resin layers and/or inorganic layers.

The display layer DL may be on a substrate SS. The display layer DL may include light-emitting diodes as display elements, a pixel circuit that is electrically connected to the light-emitting diodes, and insulating layers between them. In one or more embodiments, the display layer DL may include scan lines, data lines, and power lines connected to the pixel circuits, a scan driver to apply the scan signals to the scan lines, and fan-out wirings to connect the data lines to the display lines.

In one or more embodiments, an encapsulation layer may be additionally disposed or provided on the display layer DL. An encapsulation layer may encapsulate the light-emitting diodes on the display layer DL. In one or more embodiments, an encapsulation layer may include at least one inorganic encapsulation layer and/or at least one organic encapsulation layer. At least one inorganic encapsulation layer may include one or more inorganic layers, such as aluminum oxide (e.g., Al₂O₃), titanium oxide (e.g., TiO_{X}, wherein 0<X≤2; e.g., TiO₂), tantalum oxide (e.g., Ta₂O₅), zinc oxide (e.g., ZnO), silicon oxide (e.g., SiO_{X}, wherein 0<X≤2; e.g., SiO₂), silicon nitride (e.g., Si₃N₄ or SiNₓ, wherein 0<X≤2), and/or silicon oxynitride (e.g., Si₂N₂O or SiO_{X}N_{Y}, wherein 0<X≤2 and 0≤Y≤2; e.g., SiON). At least one organic encapsulation layer may include polymer-based materials. Examples of polymer-based materials may include an acrylic resin, an epoxy resin, polyimide, and/or polyethylene. In one or more embodiments, at least one organic encapsulation layer may include an acrylate-based resin.

An inorganic insulating layer IL may be on the display layer DL. The inorganic insulating layer IL may serve as a lower substrate to form or provide a light control layer LCL. The inorganic insulating layer IL may be composed of inorganic layers. For example, the inorganic insulating layer IL may include silicon nitride (e.g., Si₃N₄ or SiNₓ, wherein 0<X≤2), silicon oxide (e.g., SiO_{X}, wherein 0<X≤2; e.g., SiO₂), and/or silicon oxynitride (e.g., Si₂N₂O or SiO_{X}N_{Y}, wherein 0<X≤2 and 0≤Y≤2; e.g., SiON).

The inorganic layer IL will be described herein in more detail.

A light control layer LCL may contact the inorganic insulating layer IL and may be in the display area DA. The light control layer LCL may include the light-shielding patterns SP that reflect light or absorb at least part of the light and the transparent or semi-transparent organic light-transmitting patterns TP.

The light-shielding patterns SP may limit the viewing angle of the light emitted from the display layer DL by reflecting or absorbing the external light or the internally-reflected light, while the light emitted from the display layer DL may pass through the organic light-transmitting patterns TP.

Referring to FIG. 3, in one or more embodiments, the light-shielding patterns SP and the organic light-transmitting patterns TP may extend in the first direction DR1. Thus, the light-shielding patterns SP that extend in the first direction DR1 may shield the external light or part of the internally-reflected light that is inclined beyond a certain angle on the plane formed or provided by the first direction DR1 and the third direction DR3. However, embodiments of the present disclosure are not limited thereto, and a direction in which the light-shielding patterns SP and the organic light-transmitting patterns TP extend may be adjusted.

In one or more embodiments, the light-shielding patterns SP and the organic light-transmitting patterns TP may be alternately arranged or provided in the second direction DR2.

Referring to FIGS. 2 and 3, in one or more embodiments, the organic light-transmitting patterns TP may have a greater height TH in the third direction DR3 than their width TW in the second direction DR2. For example, the organic light-transmitting patterns TP may have a greater vertical length in the third direction DR3 than a horizontal length in the second direction DR2.

According to one or more embodiments of the present disclosure, the inorganic insulating layer IL may be doped with ions. The doped ions on the inorganic insulating layer IL may increase or enhance adhesion with the organic light-transmitting patterns TP by reconfiguring or rearranging and promoting or enhancing the electrostatic interactions on the surface of the inorganic insulating layer IL. For example, the doped ions may introduce or provide additional charges on the surface of the inorganic insulating layer IL, thereby strengthening or enhancing electrostatic attraction between the organic light-transmitting patterns TP.

Moreover, the doped ions on the inorganic insulating layer IL may introduce or provide new oxygen species and/or hydrogen atoms on the surface of the inorganic insulating layer IL, which increases or enhances the hydrogen bonding with the organic light-transmitting patterns TP, thereby strengthening or enhancing the interactions between/among the doped ions and hydrogen atoms and/or nitrogen atoms of the organic molecules. As a result, the ion-doped inorganic insulating layer IL may provide increased or enhanced adhesion to the organic light-transmitting patterns TP.

According to a comparative embodiment, the organic light-transmitting patterns may have a greater vertical length than a horizontal length and/or may be disposed or provided on a non-ion-doped inorganic insulating layer. In such a case, the organic light-transmitting patterns may be structurally prone to delamination from the inorganic insulating layer.

According to one or more embodiments of the present disclosure, the ion-doped inorganic insulating layer IL may provide increased or enhanced adhesion and improved or enhanced resistance to delamination of the organic light-transmitting patterns TP by directly disposing or providing the organic light-transmitting patterns TP on the ion-doped inorganic insulating layer IL.

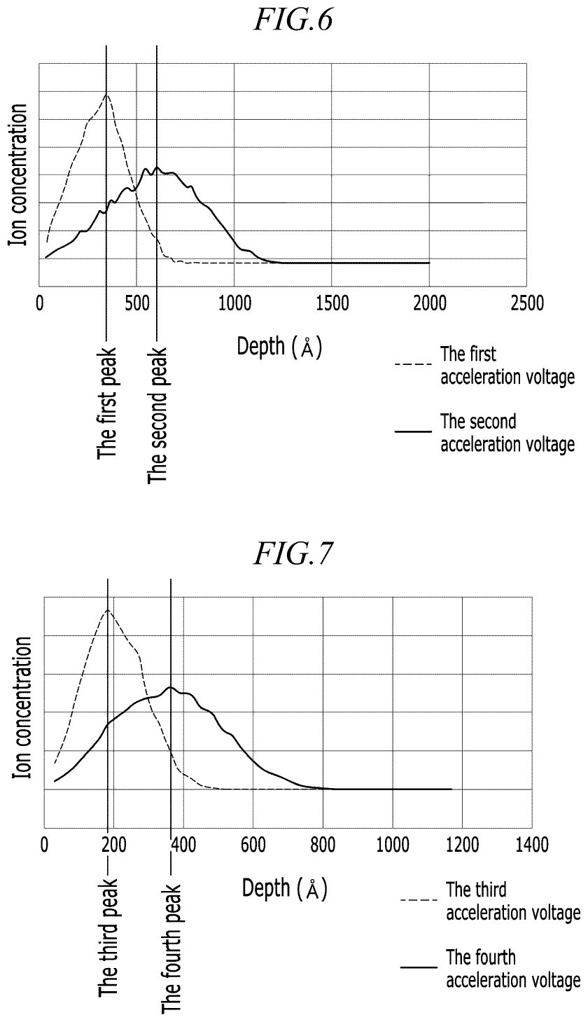

FIG. 4 is an enlarged plan view of the demarcated AA region in FIG. 1.

Referring to FIG. 4, a first pixel P1, a second pixel P2, and a third pixel P3 may be disposed or provided on a substrate SS.

The first pixel P1 may emit light having a first wavelength that corresponds to blue light. For instance, the first pixel P1 may emit light having the wavelength in the range of about 450 nm to about 495 nm. The second pixel P2 may emit light having a second wavelength that corresponds to red light. For instance, the second pixel P2 may emit light having the wavelength in the range of about 630 nm to about 780 nm. The third pixel P3 may emit light having a third wavelength that corresponds to green light. For instance, the third pixel P3 may emit light having the wavelength in the range of about 495 nm to about 570 nm. However, embodiments of the present disclosure are not limited to the foregoing ranges, and the respective wavelength ranges of emitted light may differ from the foregoing values.

The first pixel P1, the second pixel P2, and the third pixel P3 may have a rectangular form (e.g., a substantially rectangular form) among the forms of polygons. According to the present disclosure, polygons or rectangles may include shapes having rounded corners. For example, the first pixel P1, the second pixel P2, and the third pixel 3 P3 may have a rectangular form (e.g., a substantially rectangular form) having rounded corners. In one or more embodiments, the first pixel P1, the second pixel P2, and the third pixel P3 may have a circular form (e.g., a substantially circular form) or an elliptical form (e.g., a substantially elliptical form).

The sizes of the first pixel P1, the second pixel P2, and the third pixel P3 may be configured or arranged to differ from one another. For example, an area of the second pixel P2 may be smaller compared to the first pixel P1 and the third pixel P3, while the area of the first pixel P1 may be larger than that of the third pixel P3. However, embodiments of the present disclosure are not limited to these configurations or arrangements. The sizes of the first pixel P1, the second pixel P2, and the third pixel P3 may also be substantially the same, among one or more other variations.

The first pixels P1 may be provided in plurality and configured or arranged to be spaced and/or apart (e.g., spaced apart or separated) from each other in the first direction DR1. The second pixels P2 and the third pixels P3 may also be provided in plurality and configured or arranged repetitively to be spaced and/or apart (e.g., spaced apart or separated) from each other in the first direction DR1. The pixel row formed or provided by the plurality of the first pixels P1 in the first direction DR1 and the pixel row formed or provided by alternately arranging the second pixels P2 and the third pixels P3 in the first direction DR1 may be repetitively configured or arranged to be spaced and/or apart (e.g., spaced apart or separated) from each other in the second direction DR2. However, embodiments of the present disclosure are not limited to the configurations or arrangements; the first pixels P1, the second pixels P2, and the third pixels P3 may also be arranged in one or more suitable pixel structures, such as a PENTILE® arrangement structure (e.g., an RGBG matrix, an RGBG structure, or an RGBG matrix structure), a stripe structure (e.g., a substantially stripe structure), a mosaic structure (e.g., a substantially mosaic structure), and/or a delta structure (e.g., a substantially delta structure). PENTILE® is a duly registered trademark of Samsung Display Co., Ltd.

The display device DD may have a light-shielding area SHA and a light-transmitting area TA that reflects or absorbs the light emitted from the first pixel P1, the second pixel P2, and the third pixel P3. The light-shielding area SHA and the light-transmitting area TA may correspond to substantially the same areas defined by the substrate SS and its upper components. The light-shielding area SHA, where the light-shielding patterns SP are placed or provided, may extend in the first direction DR1 and overlap with the plurality of pixels. The light-shielding area SHA may also be provided in plurality and arranged or provided in the second direction DR2 to be spaced and/or apart (e.g., spaced apart or separated) from one another. However, embodiments of the present disclosure are not limited to the configurations or arrangements, and an extension and a direction in which the light-shielding area SHA is configured or arranged may vary.

The light-transmitting area TA may be defined as an area between the light-shielding areas SHA. The light-transmitting area TA may be where the organic light-transmitting patterns TP are placed or provided. As illustrated in FIG. 4, a single pixel may overlap with multiple light-shielding areas SHA and multiple light-transmitting areas TA.

A specific directional component of emitted light from the first pixel P1, the second pixel P2, and the third pixel P3 may be limited by the light-shielding patterns SP across the plurality of the light-shielding areas SHA. For example, light emitted from the first pixel P1, the second pixel P2, and the third pixel P3 in the second direction DR2 having an emission angle that exceeds certain cut-off angle may be blocked by the light-shielding patterns SP. Thus, the viewing angle of a display device DD in certain directions may be limited by the light-shielding patterns SP. The directions in which the viewing angles are limited may vary depending on a direction in which the light-shielding patterns SP extend.

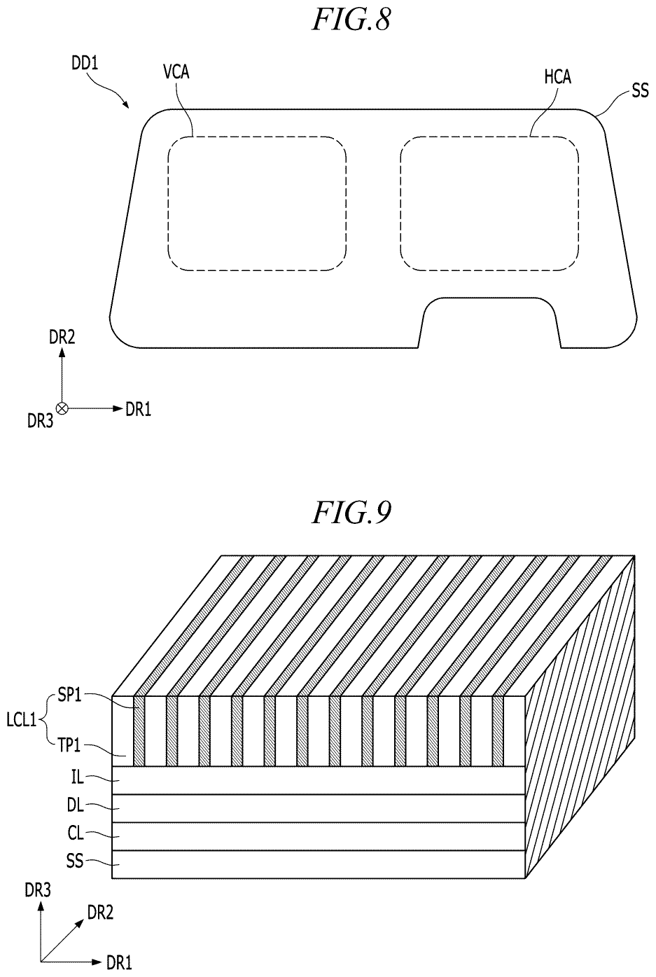

FIG. 5 is a cross-sectional view illustrating a portion of a display device according to one or more embodiments. For ease of explanation, components other than the inorganic insulating layer IL and the light control layer LCL are not provided in FIG. 5.

Referring to FIG. 5, a first area A1 relatively proximal to the light control layer LCL and a second area A2 relatively distal from the light control layer LCL may be defined within the inorganic insulating layer IL.

In one or more embodiments of the present disclosure, the ions doped in the inorganic insulating layer IL may have a higher concentration in the first area A1 than in the second area A2. An upper surface of the inorganic insulating layer IL that is proximal to the light control layer LCL may provide increased or enhanced adhesion to the organic light-transmitting patterns TP due to its proximity to the first area A1.

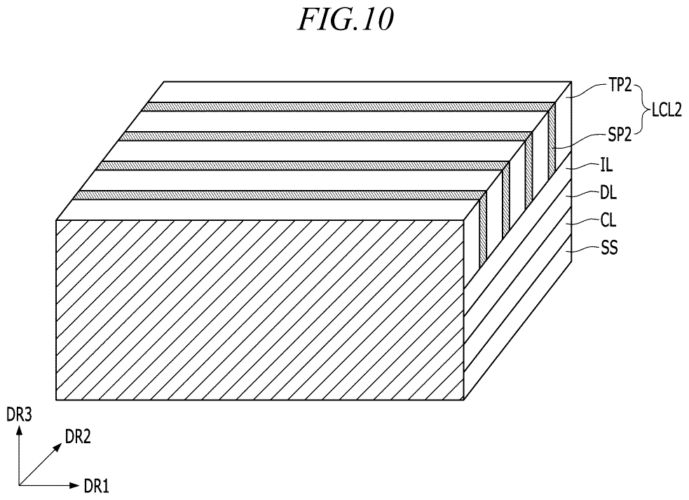

FIGS. 6 and 7 are graphs of the embodiments illustrating an ion concentration relative to a depth of the inorganic insulating layer. For example, FIG. 6 is a graph illustrating boron ion concentration with respect to a depth in the inorganic insulating layer. FIG. 7 is a graph illustrating fluoride ion concentration with respect to a depth in the inorganic insulating layer.

In one or more embodiments, the ions doped in the inorganic insulating layer IL may include boron ions.

Referring to FIG. 6, boron ions injected with the first acceleration voltage may have the first peak, where their ion concentration is maximized, while boron ions injected with the second acceleration voltage may have the second peak, where their ion concentration is maximized. In one or more embodiments, the first acceleration voltage may have a relatively lower value compared to the second acceleration voltage.

In one or more embodiments, the first peak and the second peak of the boron ion concentration doped in the inorganic insulating layer may be at a depth equal to or less than about 700 Å from an upper surface of the inorganic insulating layer IL.

In one or more embodiments, ions doped in the inorganic insulating layer IL may include fluoride ions.

Referring to FIG. 7, fluoride ions injected with the third acceleration voltage may have the third peak, where their ion concentration is maximized, while fluoride ions injected with the fourth acceleration voltage may have the fourth peak, where their ion concentration is maximized. In one or more embodiments, the third acceleration voltage may have a relatively lower value compared to the fourth acceleration voltage.

In one or more embodiments, the third peak and the fourth peak of the fluoride ion concentration doped in the inorganic insulating layer may be at a depth equal to or less than about 500 Å from an upper surface of the inorganic insulating layer IL.

In one or more embodiments, the ions doped into the inorganic insulating layer IL may include at least one selected from phosphorus ions and arsenic ions.

However, the types or kinds of ions doped into the inorganic insulating layer IL are not limited thereto and may vary.

In one or more embodiments, a touch sensing layer may be further disposed or provided between the display layer DL and the inorganic insulating layer IL. The touch sensing layer may detect external inputs, such as a touch of a finger and/or an object, such as a stylus pen, which allow the display device DD to acquire coordinate information that corresponds to the touched location. The touch sensing layer may include touch electrodes and trace lines connected to the touch electrodes. The operation method of the touch sensing layer in the present disclosure is not particularly limited. For example, the touch sensing layer may detect external inputs by using a mutual capacitance method and/or a self-capacitance method.

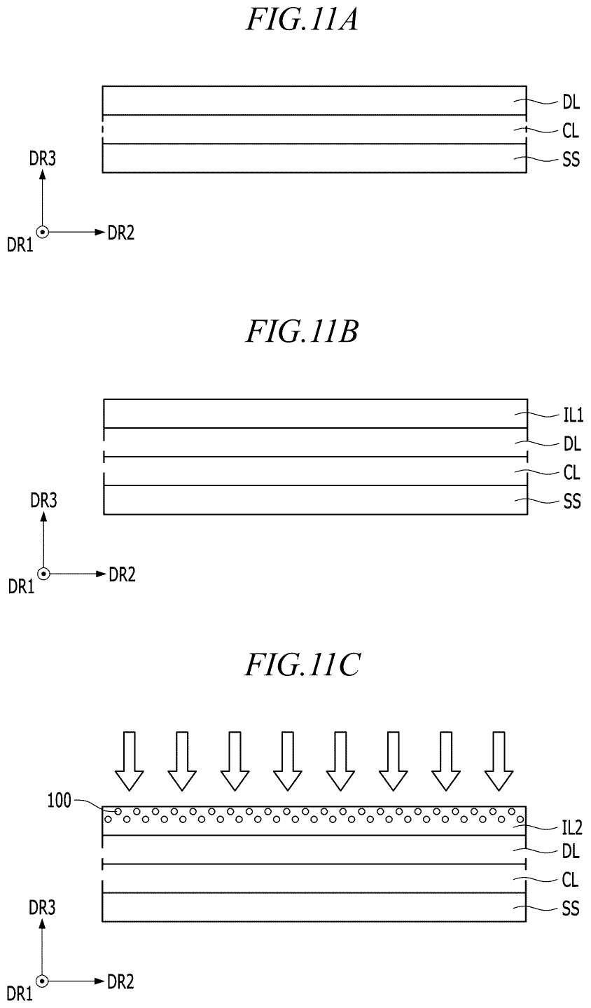

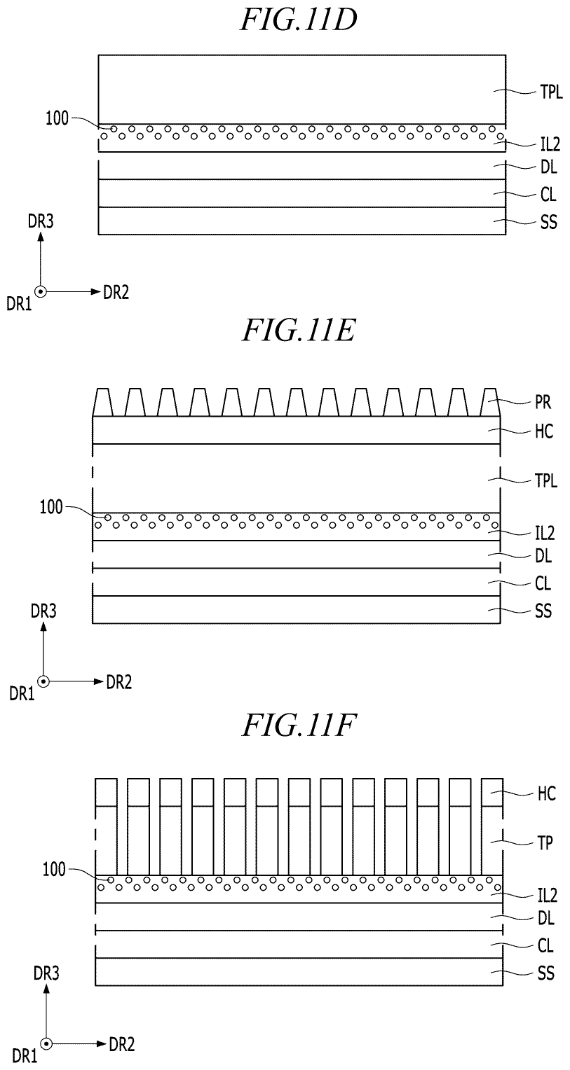

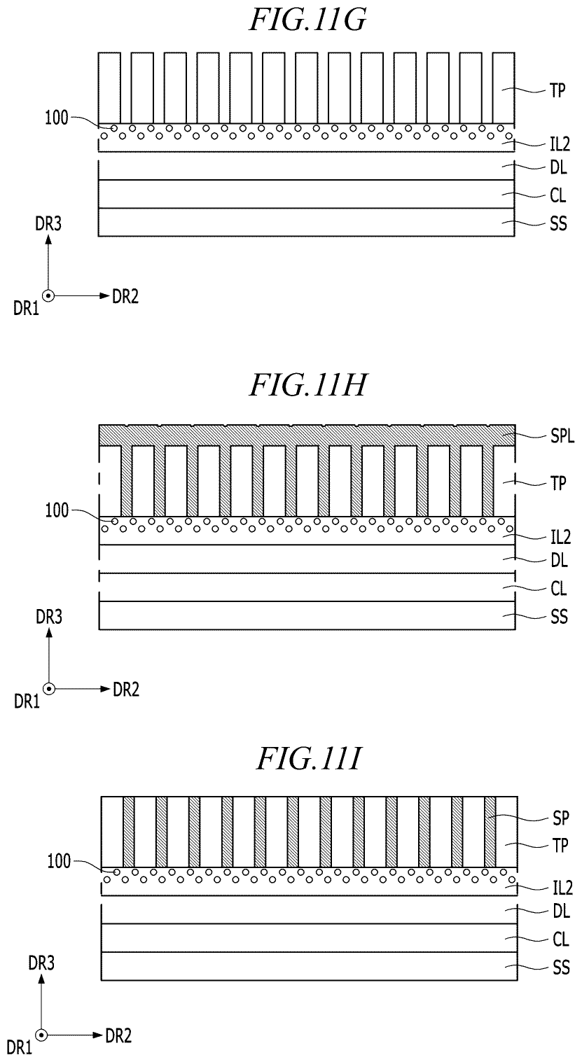

FIG. 8 is a plan view of a display device according to one or more embodiments. FIG. 9 is a perspective view illustrating a portion of the display device according to one or more embodiments. FIG. 10 is a perspective view illustrating a portion of the display device according to one or more embodiments.

Referring to FIG. 8, the shape of a display device DD1 may have a shape as illustrated in FIG. 8. The display device DD1 may be a head-up display for a vehicle.

A vertical control area VCA and a horizontal control area HCA that is spaced and/or apart (e.g., spaced apart or separated) from the vertical control area VCA, may be defined on the display device DD1. The vertical control area VCA and the horizontal control area HCA may be substantially identically defined for the substrate SS and its upper components. The horizontal control area HCA may correspond to the driver's seat of a vehicle, and the vertical control area VCA may correspond to the passenger seat, but embodiments of the present disclosure are not limited to the configurations or arrangements.

In one or more embodiments, a light control layer LCL may include a first light control layer LCL1 on the vertical control area VCA and a second light control layer on the horizontal control area HCA.

Referring to FIG. 9, the first light control layer LCL1 may include first light-shielding patterns SP1 and first organic light-transmitting patterns TP1 that extend in the second direction DR2, where a portion of the externally and/or internally-reflected light component in the first direction DR1 may be blocked by the first light-shielding patterns SP1. For example, a portion of the externally or internally-reflected light that is tilted beyond a certain angle on the plane formed or provided by the second direction DR2 and the third direction DR3 may be blocked by the first light-shielding patterns SP1 that extend in the second direction DR2. Thus, the vertical control area VCA, where the first light control layer LCL1 is positioned or provided, may have a limited viewing angle in the first direction DR1.

Referring to FIG. 10, the second light control layer LCL2 may include second light-shielding patterns SP2 and second organic light-transmitting patterns TP2 that extend in the first direction DR1, where a portion of the externally or internally-reflected light component in the second direction DR2 may be blocked by the second light-shielding patterns SP2. Thus, the horizontal control area HCA, where the second light control layer LCL2 is positioned or provided, may have a limited viewing angle in the second direction DR2.

However, embodiments of the present disclosure shall not be limited to such configurations or arrangements, and the direction in which the light-shielding patterns SP and the organic light-transmitting patterns TP, that are included in the display device, extend may be adjusted based on their position on the substrate SS.

FIGS. 11A-11I are step-by-step diagrams illustrating a manufacturing method of a display device (or a method of manufacturing a display device) according to one or more embodiments of the present disclosure.

A manufacturing method of a display device (or a method of manufacturing a display device) will be described herein in more detail with reference to FIGS. 11A-11I.

A manufacturing method of a display device (or a method of manufacturing a display device) according to one or more embodiments of the present disclosure may include the following steps (or active acts): forming or providing a circuit layer and a display layer; forming or providing an inorganic insulating (e.g., electrically insulating) layer; doping the inorganic insulating (e.g., electrically insulating) layer with ions; forming or providing an organic light-transmitting film; performing a photolithography; performing an etching; forming or providing a light-transmitting patterns; applying or providing a light-shielding layer; and forming or providing a light-shielding patterns.

Referring to FIG. 11A, the forming or providing of the circuit layer and the display layer may include forming or providing a circuit layer CL on the prepared substrate SS and forming or providing a display layer DL including a plurality of light-emitting layers on the circuit layer CL.

A manufacturing method of a display device (or a method of manufacturing a display device) according to one or more embodiments may further include forming or providing an encapsulation layer on the display layer DL after the display layer DL is formed or provided.

Referring to FIG. 11B, the forming or providing of the inorganic insulating (e.g., electrically insulating) layer may include forming or providing a non-ion-doped inorganic insulating layer IL1 on a display layer DL.

A manufacturing method of a display device (or a method of manufacturing a display device) according to one or more embodiments may further include forming or providing a touch sensing layer on the display layer DL and forming or providing an inorganic insulating layer IL1 on the touch sensing layer.

Referring to FIG. 11C, the doping of the inorganic insulating (e.g., electrically insulating) layer with ions may include doping an inorganic insulating layer IL1 (see FIG. 11B) with ions downwardly from an upper portion of the inorganic insulating layer IL1 (see FIG. 11B). The ion-doped inorganic insulating layer IL2 may include injected ions (100), and the injected ions may have relatively greater concentration in the top part that is proximal to the surface of the inorganic insulating layer IL2. The ion-doped inorganic insulating layer IL2 may provide increased or enhanced adhesion to the organic light-transmitting patters TP, as described in one or more embodiments.

In one or more embodiments, the doping of the inorganic insulating layer IL1 with ions may include doping an inorganic insulating layer IL1 with boron ions.

In one or more embodiments, the doping of the inorganic insulating layer IL1 with ions may include doping an inorganic insulating layer IL1 with fluoride ions.

In one or more embodiments, the doping of the inorganic insulating layer IL1 with ions may include doping an inorganic insulating layer IL1 with arsenic ions.

However, embodiments of the present disclosure are not limited thereto, and the doping of the inorganic insulating layer IL1 with ions may include doping an inorganic insulating layer IL1 with impurity ions (e.g., one or more types or kinds of impurity ions), including one or more of boron ions, fluoride ions, and/or arsenic ions.

Referring to FIG. 11D, the forming or providing of the organic light-transmitting film may include forming or providing an organic light-transmitting film TPL on the ion-doped inorganic insulating layer IL2.

Referring to FIG. 11E, the performing of the photolithography may include forming or providing a hard coated layer HC on the organic light-transmitting film TPL and forming or providing photoresists PR on the hard coated layer HC by using photolithography. The hard coated layer HC may serve to prevent damage (or to reduce a degree or occurrence of damage) to the organic light-transmitting patterns TP during etching.

Referring to FIG. 11F, the performing of the etching may include forming or providing organic light-transmitting patterns TP by performing an etching process on the photoresists PR and removing the remaining photoresist PR (see FIG. 11E) from the upper portion of the organic light-transmitting patterns TP.

Referring to FIG. 11G, the forming or providing of the light-transmitting patterns may include removing one or more structures, such as the hard coated layer HC, that remain on upper portion of the organic light-transmitting patterns TP.

However, embodiments of the present disclosure are not limited thereto, and the performing of the photolithography and/or the performing of the etching may not be provided.

Referring to FIG. 11H, the applying or providing of the light-shielding layer may include applying or providing a light-shielding layer SPL to cover the areas between the organic light-transmitting patterns TP.

Referring to FIG. 11I, the applying or providing of the light-shielding patterns may include forming or providing light-shielding patterns SP by removing part of the light-shielding layer SPL that covers the organic light-transmitting patterns TP to expose the organic light-transmitting patterns TP.

A manufacturing method of a display device (or a method of manufacturing a display device) according to one or more embodiments of the present disclosure may increase or enhance the resistance to delamination of the organic light-transmitting patterns TP by directly forming or providing the organic light-transmitting patterns TP on the ion-doped inorganic insulating layer IL2 and may provide a display device having improved or enhanced reliability (e.g., structural reliability).

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

Although one or more embodiments of the present disclosure have been described with reference to the accompanying drawings, it should be understood that the present disclosure should not be limited to these embodiments but one or more suitable modifications and changes can be made by one ordinary skilled in the art within the spirit and scope of the appended claims and equivalents thereof, the detailed description of the present disclosure, and the accompanying drawings. Therefore, the present disclosure is not limited to the embodiments as described, but the scope of the present disclosure should be determined by the appended claims and equivalents thereof.

What is claimed is:

1. A display device comprising:
a substrate;
a circuit layer on the substrate;
a display layer provided on the circuit layer and comprising a plurality of light-emitting layers;
an inorganic insulating layer disposed on the display layer, wherein an upper portion of the inorganic insulating layer is doped with ions; and
a light control layer comprising a plurality of light-shielding patterns on the inorganic insulating layer and organic light-transmitting patterns provided between the plurality of light-shielding patterns and contacting the inorganic insulating layer.

2. The display device as claimed in claim 1, wherein the plurality of light-shielding patterns and the organic light-transmitting patterns extend in a first direction and
are alternately provided in a second direction that crosses the first direction.

3. The display device as claimed in claim 2, wherein the organic light-transmitting patterns have a greater height in a third direction, which crosses the second direction, than a width in the second direction.

4. The display device as claimed in claim 1, wherein a first area and a second area are defined in the inorganic insulating layer, the first area being relatively proximal to the light control layer and the second area being relatively distal to the light control layer, and
wherein the ions have a greater concentration in the first area than in the second area.

5. The display device as claimed in claim 1, wherein the ions comprise boron ions.

6. The display device as claimed in claim 5, wherein a concentration peak of the ions is at a depth equal to or less than 700 Å from an upper surface of the inorganic insulating layer.

7. The display device as claimed in claim 1, wherein the ions comprise fluoride ions.

8. The display device as claimed in claim 7, wherein a concentration peak of the ions is at a depth equal to or less than 500 Å from an upper surface of the inorganic insulating layer.

9. The display device as claimed in claim 1, wherein the ions comprise at least one selected from phosphorus ions and arsenic ions.

10. The display device as claimed in claim 1, further comprising a touch sensing layer between the display layer and the inorganic insulating layer.

11. The display device as claimed in claim 1, wherein a vertical control area and a horizontal control area are defined in the substrate, the horizontal control area being spaced apart from the vertical control area,
wherein the light control layer comprises:
a first light control layer provided in the vertical control area and comprising first light-shielding patterns that extend in a first direction; and
a second light control layer provided in the horizontal control area and comprising second light-shielding patterns that extend in a second direction that crosses the first direction.

12. A method of manufacturing a display device, the method comprising:
providing a circuit layer on a substrate;
providing a display layer on the circuit layer, wherein the display layer comprises a plurality of light-emitting layers;
providing an inorganic insulating layer on the display layer;
doping the inorganic insulating layer with ions downwardly from an upper portion of the inorganic insulating layer;
providing an organic light-transmitting film on the doped inorganic insulating layer;
providing organic light-transmitting patterns by patterning the organic light-transmitting film; and
providing light-shielding patterns between the organic light-transmitting patterns.

13. The method as claimed in claim 12, wherein the doping of the inorganic insulating layer with ions comprises doping with boron ions.

14. The method as claimed in claim 12, wherein the doping of the inorganic insulating layer with ions comprises doping with fluoride ions.

15. The method as claimed in claim 12, further comprising providing a touch sensing layer between the display layer and the inorganic insulating layer.

16. The method as claimed in claim 12, wherein in the providing of the organic light-transmitting patterns:
the organic light-transmitting patterns are extended in a first direction in a vertical control area defined on the substrate and are extended in a second direction in a horizontal control area defined on the substrate,
wherein the horizontal control area is spaced apart from the vertical control area, and
wherein the second direction crosses the first direction.

17. The method as claimed in claim 12, wherein in the doping of the inorganic insulating layer with ions, the ions are injected at an acceleration voltage greater than or equal to 5 keV and smaller than or equal to 10 keV.

18. An electronic device, comprising a display device comprising:
a substrate;
a circuit layer on the substrate;
a display layer provided on the circuit layer and comprising a plurality of light-emitting layers;
an inorganic insulating layer on the display layer, wherein an upper portion of the inorganic insulating layer is doped with ions; and
a light control layer comprising a plurality of light-shielding patterns on the inorganic insulating layer and organic light-transmitting patterns provided between the plurality of light-shielding patterns and contacting the inorganic insulating layer.

19. The electronic device as claimed in claim 18, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
